(19) United States
(12) Patent Application Publication
(10) Pub. No.: US 2023/0083830 A1
(43) Pub. Date: Mar. 16, 2023

(54) PIEZOELECTRIC FILM LAMINATED BODY AND MANUFACTURING METHOD OF THE SAME

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: AKIHIKO TESHIGAHARA, Nisshin-shi (JP); TETSUYA ENOMOTO, Nisshin-shi (JP); HIDEO YAMADA, Nisshin-shi (JP)

(21) Appl. No.: 17/943,600

(22) Filed: Sep. 13, 2022

(30) Foreign Application Priority Data
Sep. 15, 2021 (JP) 2021-150235

(51) Int. Cl. H01L 41/08; H01L 41/187; H01L 41/316; H01L 41/319

(52) U.S. Cl. CPC H01L 41/0815; H01L 41/187; H01L 41/316; H01L 41/319; H03H 9/02031

(57) ABSTRACT

A piezoelectric film laminated body includes a metal film, an amorphous film, and a scandium aluminum nitride film. The amorphous film has an insulation property and is disposed on the metal film. The scandium aluminum nitride film is disposed on the amorphous film and is in contact with a surface of the amorphous film.

### CROSS REFERENCE TO RELATED APPLICATION

The present application claims the benefit of priority from Japanese Patent Application No. 2021-150235 filed on Sep. 15, 2021. The entire disclosure of the above application is incorporated herein by reference.

### TECHNICAL FIELD

The present disclosure relates to a piezoelectric film laminated body and a manufacturing method of a piezoelectric film laminated body.

### BACKGROUND

There has been known a piezoelectric film laminated body including a lower electrode and a scandium aluminum nitride (ScAlN) film disposed on the lower electrode. The ScAlN film is a piezoelectric film. The lower electrode is an electrode disposed under the ScAlN film. This piezoelectric film laminated body constitutes a part of various devices.

### SUMMARY

A piezoelectric film laminated body according to a first aspect of the present disclosure includes a metal film, an amorphous film having an insulation property and disposed on the metal film, and a ScAlN film disposed on the amorphous film and being in contact with a surface of the amorphous film.

A piezoelectric film laminated body according to a second aspect of the present disclosure includes an amorphous film having conductivity, and a ScAlN film disposed on the amorphous film and being in contact with a surface of the amorphous film.

The present disclosure also discloses a manufacturing method of the piezoelectric film laminated body according to the first aspect, and a manufacturing method of the piezoelectric film laminated body according to the second aspect.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view of a piezoelectric film laminated body according to a first embodiment;

FIG. 2 is a flowchart illustrating a manufacturing method of the piezoelectric film laminated body according to the first embodiment;

FIG. 3 is a graph showing a relationship between a leaving time in the atmosphere and a film thickness of an amorphous film formed by leaving in the atmosphere in a process of forming the amorphous film in FIG. 2;

FIG. 4 is a graph showing a relationship between the leaving time in the atmosphere in the process of forming the amorphous film in FIG. 2 and the crystallinity of a ScAlN film;

FIG. 5 is a cross-sectional view of a piezoelectric film laminated body according to a third embodiment;

FIG. 6 is a cross-sectional view of a piezoelectric film laminated body according to a fourth embodiment;

FIG. 7 is a flowchart illustrating a manufacturing method of the piezoelectric film laminated body according to the fourth embodiment;

FIG. 8 is a cross-sectional view of a microphone according to a fifth embodiment;

FIG. 9 is a perspective view of a bulk acoustic wave (BAW) resonator according to a sixth embodiment;

FIG. 10 is a perspective view of a surface acoustic wave (SAW) device according to a seventh embodiment; and

FIG. 11 is a cross-sectional view of a micro electro mechanical systems (MEMS) resonator according to an eighth embodiment.

### DETAILED DESCRIPTION

Next, a relevant technology is described only for understanding the following embodiments. When manufacturing a piezoelectric film laminated body including an electrode and a ScAlN film disposed on the electrode, if the ScAlN film is formed in contact with a surface of the electrode, the crystallinity of the ScAlN film may decrease due to a material constituting the electrode or the magnitude of a residual stress of the ScAlN film. If the crystallinity of the ScAlN film decreases, the piezoelectricity of the ScAlN film decreases.

A piezoelectric film laminated body according to a first aspect of the present disclosure includes a metal film, an amorphous film having an insulation property and disposed on the metal film, and a ScAlN film disposed on the amorphous film and being in contact with a surface of the amorphous film.

According to the first aspect, the ScAlN film is disposed in contact with the surface of the amorphous film. Therefore, ScAlN can be self-oriented without being affected by a crystal structure of a base member disposed under the ScAlN film. Therefore, the ScAlN film can have higher crystallinity than a case where the ScAlN film is formed in contact with a surface of a base member having a crystal structure. Therefore, the piezoelectric film laminated body including the ScAlN film having high crystallinity can be obtained.

A piezoelectric film laminated body according to a second aspect of the present disclosure includes an amorphous film having conductivity, and a ScAlN film disposed on the amorphous film and being in contact with a surface of the amorphous film.

According to the second aspect, the ScAlN film is disposed in contact with the surface of the amorphous film. Therefore, ScAlN can be self-oriented without being affected by a crystal structure of a base member disposed under the ScAlN film. Therefore, the ScAlN film can have higher crystallinity than a case where the ScAlN film is formed in contact with a surface of a base member having a crystal structure. Therefore, the piezoelectric film laminated body including the ScAlN film having high crystallinity can be obtained.

A manufacturing method of a piezoelectric film laminated body according to a third aspect of the present disclosure includes forming a metal film, forming an amorphous film having an insulation property on the metal film, and forming a ScAlN film on the amorphous film to be in contact with a surface of the amorphous film. The forming the amorphous film includes oxidizing or nitriding a surface layer of the metal film to form the amorphous film.

By the manufacturing method according to the third aspect, the piezoelectric film laminated body according to the first aspect can be manufactured. In the manufacturing method according to the third aspect, the ScAlN film is formed in contact with the surface of the amorphous film. Thus, ScAlN can be self-oriented without being affected by a crystal structure of a base member disposed under the ScAlN film. Therefore, it is possible to form the ScAlN film having higher crystallinity than a case where the ScAlN film is formed in contact with a surface of a base member having a crystal structure. Therefore, it is possible to manufacture the piezoelectric film laminated body including the ScAlN film having high crystallinity.

A manufacturing method of a piezoelectric film laminated body according to a fourth aspect of the present disclosure includes forming an amorphous film having conductivity, and forming a ScAlN film on the amorphous film to be in contact with a surface of the amorphous film. The forming the amorphous film includes performing an ion implantation or a plasma treatment to a metal film to form the amorphous film.

By the manufacturing method according to the fourth aspect, the piezoelectric film laminated body according to the second aspect can be manufactured. In the manufacturing method according to the fourth aspect, the ScAlN film is formed in contact with the surface of the amorphous film. Thus, ScAlN can be self-oriented without being affected by a crystal structure of a base member disposed under the ScAlN film. Therefore, it is possible to form the ScAlN film having higher crystallinity than a case where the ScAlN film is formed in contact with a surface of a base member having a crystal structure. Therefore, it is possible to manufacture the piezoelectric film laminated body including the ScAlN film having high crystallinity.

Embodiments of the present disclosure will be described hereinafter with reference to the drawings. In the embodiments described hereinafter, the same or equivalent parts will be designated with the same reference numerals.

### First Embodiment

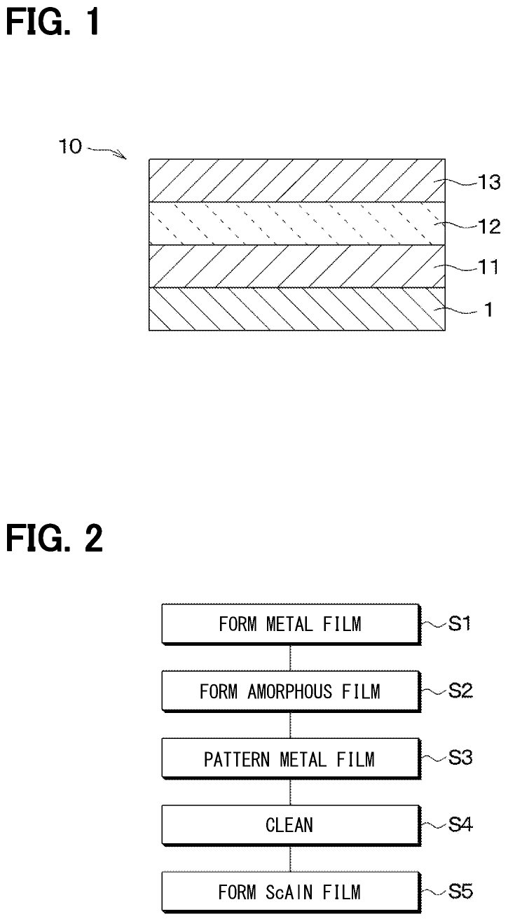

As shown in FIG. 1, a piezoelectric film laminated body 10 according to a first embodiment includes a substrate 1, a metal film 11, an amorphous film 12, and a ScAlN film 13.

The substrate 1 is made of a semiconductor material, an insulating material, or the like. As the substrate 1, for example, a silicon (Si) substrate is used.

The metal film 11 is a film made of a metal material. The metal film 11 is used as a lower electrode in a device. The metal film 11 is disposed on the substrate 1. The metal film 11 is in contact with a surface of the substrate 1. One or more other films may be disposed between the metal film 11 and the substrate 1. That is, the metal film 11 may be in contact with a surface of another film on the substrate 1.

The amorphous film 12 is disposed on the metal film 11. The amorphous film 12 is in contact with a surface of the metal film 11. The amorphous film 12 is used as a base member for the ScAlN film 13.

The amorphous film 12 is a film made of an amorphous material having an insulation property. In the present disclosure, the term “insulation” means that an electrical resistivity (that is, a volume resistivity) is 10⁴ Ω·m or more. Amorphous is a state of matter that does not have a crystal structure. The fact that the material constituting the amorphous film 12 is amorphous is confirmed by performing electron diffraction measurement on the amorphous film 12. When the measurement result is a halo pattern, the material constituting the amorphous film 12 is amorphous. Examples of the material constituting the amorphous film 12 include materials containing metal oxides, metal nitrides and the like.

As can be seen from experimental results described later, in a range where a film thickness of the amorphous film 12 is smaller than 1.0 nm, the crystallinity of the ScAlN film 13 increases with increase in the film thickness of the amorphous film 12. In a range where the film thickness of the amorphous film 12 is 1.0 nm or more, the level of the crystallinity of the ScAlN film 13 is almost the same regardless of the film thickness of the amorphous film 12, and the crystallinity of the ScAlN film 13 is high as compared with the range where the film thickness of the amorphous film 12 is smaller than 1.0 nm. Thus, the film thickness of the amorphous film 12 is preferably 1.0 nm or more.

However, when the film thickness of the amorphous film 12 becomes thicker, the overall piezoelectricity of a composite film including the ScAlN film 13 and the amorphous film 12 is impaired. Therefore, the film thickness of the amorphous film 12 is set so that the piezoelectricity of the composite film is not significantly impaired. For example, when the film thickness of the amorphous film 12 is 1/10 or less of the film thickness of the ScAlN film 13, the piezoelectricity of the composite film is not significantly impaired.

The film thickness of the amorphous film 12 is measured using an ellipsometer or a transmission electron microscope (TEM) image of a cross section of the amorphous film 12. When a TEM image is used, an average value of measured values at 10 points is used as the film thickness of the amorphous film 12.

The ScAlN film 13 is a piezoelectric film made of ScAlN. The ScAlN film 13 is disposed on the amorphous film 12. The ScAlN film 13 is in contact with the surface of the amorphous film 12.

The Sc concentration of the ScAlN film 12 may be any concentration within a range from 0 atomic % to 45 atomic % both inclusive. The Sc concentration is a proportion of the number of scandium atoms in total of the number of the scandium atoms and the number of aluminum atoms as 100 atomic %. Atomic% refers to atomic percent. Sc concentration is measured by Rutherford backscattering spectrometry (RBS). The Sc concentrations described in the present disclosure are values measured under the following measurement conditions using the following apparatus.

Name of apparatus: Pelletron 3SDH manufactured by National Electrostatics Corporation

Measurement conditions
RBS measurement
Incident ion: 4 He++
Incident energy: 2300 keV
Incident angle: 0 deg
Scattering angle: 160 deg
Sample current: 13 nA
Beam diameter: 2 mmφ
In-plane rotation: None
Irradiation: 70 μC

Next, a manufacturing method of the piezoelectric film laminated body 10 according to the present embodiment will be described. As shown in FIG. 2, the manufacturing method of the piezoelectric film laminated body 10 includes S1 of forming the metal film 11, S2 of forming the amorphous film 12, and S5 of forming the ScAlN film 13.

First, in S1, the metal film 11 is formed on the substrate 1. In order to form the amorphous film 12 by oxidation or nitridation of the metal film 11, the metal film 11 is formed of a material containing at least one metal element selected from the group consisting of molybdenum (Mo), aluminum (Al), and titan (T)i. Mo, Al, and Ti are metal elements used as electrode materials, and can form an insulating metal compound by oxidation or nitridation. The metal film 11 may be composed of an alloy containing two or more metal elements among Mo, Al, and Ti.

Subsequently, in S2, the amorphous film 12 is formed. That is, the amorphous film 12 having an insulation property and being in contact with the surface of the metal film 11 is formed. By oxidizing or nitriding a surface layer of the metal film 11, the amorphous film 12 is formed of a material containing an oxide or a nitride of at least one metal element selected from the group consisting of Mo, Al, and Ti.

Here, as an example, a case where the amorphous film 12 is composed of a material containing Mo oxide will be described. First, in S1, the metal film 11 made of a material containing Mo is formed by a sputtering method to be in contact with the surface of the substrate 1 that is made of the Si substrate. In this way, the metal film 11 is disposed in contact with the surface of the base member made of a material other than aluminum nitride (AlN). That is, there is no AlN film under the metal film 11. Then, in S2, the surface layer of the metal film 11 is oxidized to form the amorphous film 12 made of a material containing Mo oxide. As the oxidation method, leaving in the atmosphere or a heat treatment is adopted.

When the leaving in the atmosphere is adopted, the metal film 11 is left in the atmosphere. The film thickness of the amorphous film 12 to be formed is determined by the leaving time. Therefore, the leaving time is set so that the film thickness of the amorphous film 12 becomes the above-described size.

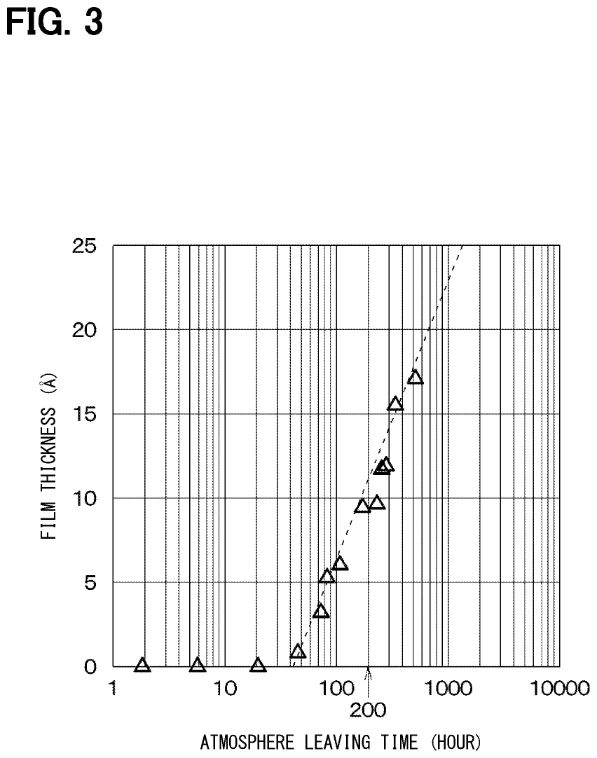

FIG. 3 shows a relationship between the leaving time of the metal film 11 mainly composed of Mo and the film thickness of the amorphous film 12 when the metal film 11 is left in the atmosphere at normal temperature and normal humidity. The horizontal axis is the leaving time in the atmosphere. The film thickness shown in FIG. 3 is a value measured using an ellipsometer. As shown in FIG. 3, the film thickness of the amorphous film 12 increases with increase in the leaving time. By setting the leaving time to about 200 hours, the film thickness of the amorphous film 12 can be made about 10 Å (that is, 1.0 nm). In FIG. 3, the film thickness is 0 when the leaving time is 40 hours or less. This is because the film thickness of the amorphous film 12 could not be measured when the leaving time was 40 hours or less. In the present embodiment, the leaving time is set to be longer than 40 hours. Accordingly, the amorphous film 12 having a film thickness of about 1 Å (that is, 0.1 nm) or more can be obtained.

On the other hand, when the heat treatment is adopted, the metal film 11 is heated in an atmosphere in which oxygen is present. The heating temperature at this time is preferably 100° C. or higher and 250° C. or lower. The thickness of the amorphous film 12 is 6.5 nm by heat-treating the metal film 11 mainly composed of Mo with a quartz tube under the conditions of 100% oxygen, atmospheric pressure, temperature of 200° C. for 1 hour.

In a manufacturing method of a conventional device provided with a lower electrode, a process of patterning a metal film is performed after a process of forming the metal film. In the process of patterning the metal film, the metal film is patterned into a predetermined shape by photolithography and etching to form the lower electrode.

Unlike the present embodiment, it is assumed that S5 of forming the ScAlN film 13 is performed after S1 of forming the metal film 11 without performing S2 of forming the amorphous film 12. In this case, the process of patterning the metal film 11 is performed after the process of forming the metal film 11 and before S5 of forming the ScAlN film 13. In this case, the metal film 11 is exposed to the atmosphere between the time when the metal film 11 is formed and the time when the ScAlN film 13 starts to be formed. Therefore, even if S2 of forming the amorphous film 12 is not performed, the surface layer of the metal film 11 is naturally oxidized to some extent.

However, even in view of these processes, for mass production of devices, the time interval from the formation of the metal film 11 to the formation of the ScAlN film 13 is usually about one day at the longest. As can be seen from FIG. 3, the film thickness of the oxide film formed when the natural oxidation time is about one day is too small to be measured, and the film thickness does not reach the preferable film thickness (that is, 1.0 nm or more) of the amorphous film 12 described above.

After S2 of forming the amorphous film 12, S5 of forming the ScAlN film 13 is performed. That is, the ScAlN film 13 is formed to be in contact with the surface of the amorphous film 12. The ScAlN film 13 is formed at a predetermined film formation temperature by a reactive sputtering method. As a result, the piezoelectric film laminated body 10 according to the present embodiment is manufactured.

The manufacturing method of the piezoelectric film laminated body 10 according to the present embodiment includes S3 of patterning the metal film 11 as in the manufacturing method of the conventional device described above. S2 of forming the amorphous film 12 may be performed at any timing before or after S3 of patterning the metal film 11.

However, due to S3 of patterning the metal film 11, various contaminants may adhere to the surface of the metal film 11. If the surface layer of the metal film 11 is oxidized with the contaminants attached, there is a high possibility that the contaminants will diffuse into the metal film 11. In particular, if the surface layer of the metal film 11 is oxidized by thermal oxidation with the contaminants attached, there is a high possibility that the heating device will be contaminated. Therefore, it is preferable that S2 of forming the amorphous film 12 is performed before S3 of patterning the metal film 11, as shown in FIG. 2. Accordingly, it is possible to restrict the diffusion of the contaminants into the metal film and the contamination of the heating device by the contaminants.

Further, as shown in FIG. 2, the manufacturing method of the piezoelectric film laminated body 10 according to the present embodiment includes S4 of cleaning. S4 is performed after S2 of forming the amorphous film 12 and before S5 of forming the ScAlN film 13. In S4, the surface layer of the amorphous film 12 is removed to remove contaminants on the amorphous film 12.

S4 of cleaning is performed to improve the crystallinity of ScAlN when the ScAlN film 13 is formed. S4 of cleaning is performed in a film forming chamber for forming the ScAlN film 13 or in a separate chamber capable of transporting while maintaining a vacuum state. In S4 of cleaning, Ar gas is introduced into the chamber and discharged to generate Ar ions, and the surface of the amorphous film 12 is irradiated with Ar ions to remove the contaminants on the amorphous film 12 by sputtering. At this time, not only the contaminants but also the surface layer of the amorphous film 12 is removed, so that the film thickness of the amorphous film 12 is reduced.

Therefore, in S2 of forming the amorphous film 12, the thickness of the amorphous film 12 is set to the sum of a target thickness of the amorphous film 12 after S4 and a thickness of the amorphous film 12 to be removed in S4. Accordingly, the thickness of the amorphous film 12 after S4 can be set to a thickness within the above-described film thickness range.

As described above, the piezoelectric film laminated body 10 according to the present embodiment includes the metal film 11, the amorphous film 12 having the insulation property, and the ScAlN film 13. Further, the manufacturing method of the piezoelectric film laminated body 10 according to the present embodiment includes S1 of forming the metal film 11, S2 of forming the amorphous film 12, and S5 of forming the ScAlN film 13.

Here, unlike the present embodiment, when a ScAlN film is formed in contact with a surface of an electrode, the crystallinity of the obtained ScAlN film is lowered depending on the material constituting the electrode. In particular, when the electrode is made of a material containing Mo, the crystallinity of the obtained ScAlN film is lowered. Further, the crystallinity of the obtained ScAlN film is lowered depending on the magnitude of the residual stress of the ScAlN film, that is, when the residual stress of the ScAlN film is larger than an appropriate magnitude. When the crystallinity of the ScAlN film is lowered, the piezoelectricity of the ScAlN film decreases.

On the other hand, according to the present embodiment, the ScAlN film 13 is formed in contact with the surface of the amorphous film 12. Therefore, ScAlN can be self-oriented without being affected by a crystal structure of a base member disposed under the ScAlN film. That is, when a base member has a crystal structure, the lattice constant of the crystal structure affects the crystal growth of ScAlN. On the other hand, according to the present embodiment, ScAlN can be crystal-grown without being affected by a crystal structure of a base member. Therefore, the ScAlN film 13 can have higher crystallinity than a case where the ScAlN film 13 is formed in contact with a surface of a base member having a crystal structure. By increasing the crystallinity of the ScAlN film, the piezoelectricity of the ScAlN film can be improved.

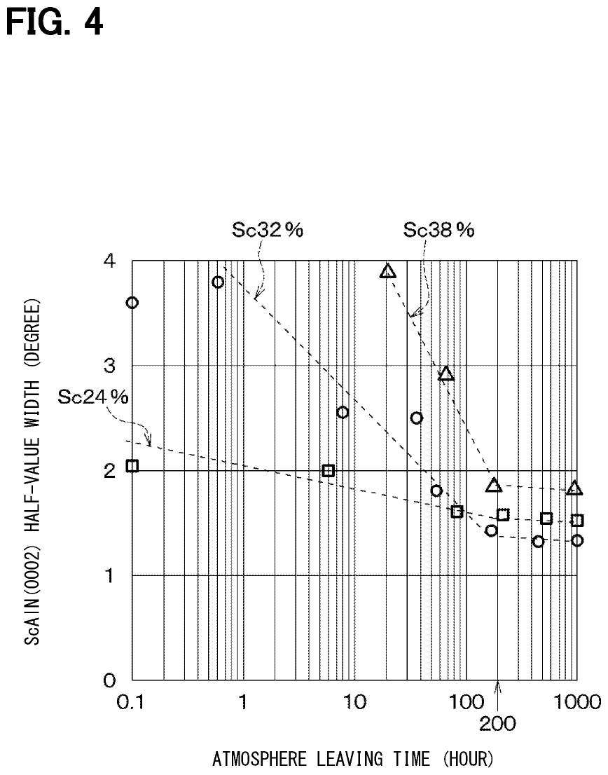

FIG. 4 shows the results of experiments conducted by the present inventors. FIG. 4 is a graph showing the relationship between the crystallinity of the ScAlN film and the leaving time of the metal film 11 in the atmosphere. The vertical axis of FIG. 4 is the half-value width of the locking curve for the X-ray diffraction peak of the (0002) plane of the ScAlN crystal. The horizontal axis of FIG. 4 is the leaving time when the amorphous film 12 is formed by leaving the metal film 11 in the atmosphere. Sc 24%, Sc 32%, and Sc 38% in FIG. 4 indicate that the Sc concentrations of the ScAlN film 13 are 24 atomic %, 32 atomic %, and 38 atomic %, respectively.

The present inventors produced piezoelectric film laminated bodies 10 in which the Sc concentration of the ScAlN film 13 is 24 atomic %, 32 atomic %, or 38 atomic %, and the thickness of the amorphous film 12 is different. In each of the piezoelectric film laminated bodies 10, the metal film 11 is made of a material containing Mo, and the amorphous film 12 is made of a material containing Mo oxide.

The present discloser formed the metal film 11 on a Si substrate by a sputtering method. The film forming conditions of the metal film 11 were as follows.

Target type: Mo target

Target size: 100 mm in diameter

Atmosphere type: Ar

Pressure: 0.2 Pa

Substrate temperature: 400° C.

DC power: 250 W

Film thickness: 70 nm

Then, the metal film 11 was left in the atmosphere to form the amorphous film 12 on the metal film 11. At this time, the amorphous films 12 having different film thicknesses were formed by setting the leaving time to various times.

Then, the ScAlN film 13 was formed on the amorphous film 12 by a reactive sputtering method. The film forming conditions of the ScAlN film 13 were as follows.

Target type: ScAl target

Target size: 100 mm in diameter

Distance between Si substrate and target: 200 mm

DC power: 800 W

Pulse frequency: 20 kHz

Pulse length: 4 μs

Gas flow rate N₂: 28 sccm, Ar: 28 sccm

Gas pressure: 0.2 Pa

Si substrate temperature: 370° C.

Specific resistance of Si substrate: ≥1×10³ Ω·cm

At this time, three ScAl targets having preset Sc concentrations were used so that the Sc concentrations of the ScAlN film 13 after film formation were 24 atomic %, 32 atomic %, and 38 atomic %.

When the half-value width of the vertical axis in FIG. 4 decreases, the crystallinity of ScAlN increases. In FIG. 4, when the Sc concentration of the ScAlN film 13 is 24 atomic %, 32 atomic %, or 38 atomic %, the half-value width decreases with increase in the leaving time in the range where the leaving time is less than 200 hours. In the range where the leaving time is 200 hours or more, the ratio of the decrease in the half-value width to the increase in the leaving time is smaller than in the range where the leaving time is smaller than 200 hours. That is, in the range of the leaving time of 200 hours or more, the half-value width is close to the minimum value of the half-value width at each Sc concentration and is almost constant even if the leaving time increases. That is, in the range where the leaving time is 200 hours or more, the half-value width is within the range close to the minimum value. When the leaving time is 200 hours or more, the effect of improving the crystallinity is saturated. From the above results, it can be seen that it is preferable that the leaving time is long, and in particular, the leaving time is preferably 200 hours or more in order to enhance the crystallinity of ScAlN.

In FIG. 3, the measured value of the film thickness at the two positions where the leaving time is around 200 hours is about 10 Å (that is, about 1.0 nm). Therefore, the film thickness of the amorphous film 12 is preferably 1.0 nm or more.

Note that FIG. 4 shows the results when the Sc concentration of the ScAlN film 13 is 24 atomic % or more and 38 atomic % or less, but even when the Sc concentration is other than that range, it is presumed that the half-value width is within the range close to the minimum value when the leaving time is 200 hours or more.

Conventionally, when a metal film containing Mo is used as the base member of the ScAlN film, a base member composed of AlN called a seed layer is used under the metal film in order to improve the crystallinity of Mo. That is, in the process of forming the metal film, the metal film is formed in contact with the base member composed of AlN.

On the other hand, according to the present embodiment, the ScAlN film 13 can be formed without being affected by the crystallinity of the metal film 11. That is, the crystallinity of the metal film 11 does not affect the crystallinity of the ScAlN film 13. Therefore, according to the present embodiment, there is also an effect that the restriction on the crystallinity of Mo is removed.

Therefore, according to the present embodiment, when the metal film 11 is made of a material containing Mo and the amorphous film 12 is made of a material containing Mo oxide, the metal film 11 can be disposed in contact with the surface of the substrate 1 as the base member composed of a material other than AlN. Further, in this case, the degree of freedom in film forming conditions of the metal film 11 is increased, and it is possible to select film forming conditions, for example, specialized for controlling the film stress while ignoring the crystallinity of Mo. Even when the metal film 11 is disposed in contact with the surface of another film on the substrate 1, the film serving as the base member of the metal film 11 may be made of a material other than AlN.

### Second Embodiment

In the present embodiment, unlike the first embodiment, the amorphous film 12 is formed in S2 by a film forming method. Examples of the film forming method include a physical vapor deposition method and a chemical vapor deposition method. When forming the amorphous film 12 by the film forming method, “lowering a substrate temperature”, “increasing a film forming pressure”, “increasing an input power to increase a film formation speed”, and the like are performed with respect to conditions for forming a film having a crystal structure. Accordingly, the amorphous film 12 can be formed.

In S1, the metal film 11 made of a material containing a metal element used as an electrode material is formed. Examples of the metal element used as the electrode material include ruthenium (Ru), platinum (Pt), gold (Au) and the like in addition to Mo, Al and Ti. In the present embodiment, a metal element contained in a material constituting the amorphous film 12 may be the same as or different from the metal element contained in the material constituting the metal film 11.

The other configurations of the piezoelectric film laminated body 10 and the manufacturing method of the piezoelectric film laminated body 10 are similar to those in the first embodiment. Also in the present embodiment, the effects of the configurations common to those of the first embodiment can be obtained in the same manner as in the first embodiment.

### Third Embodiment

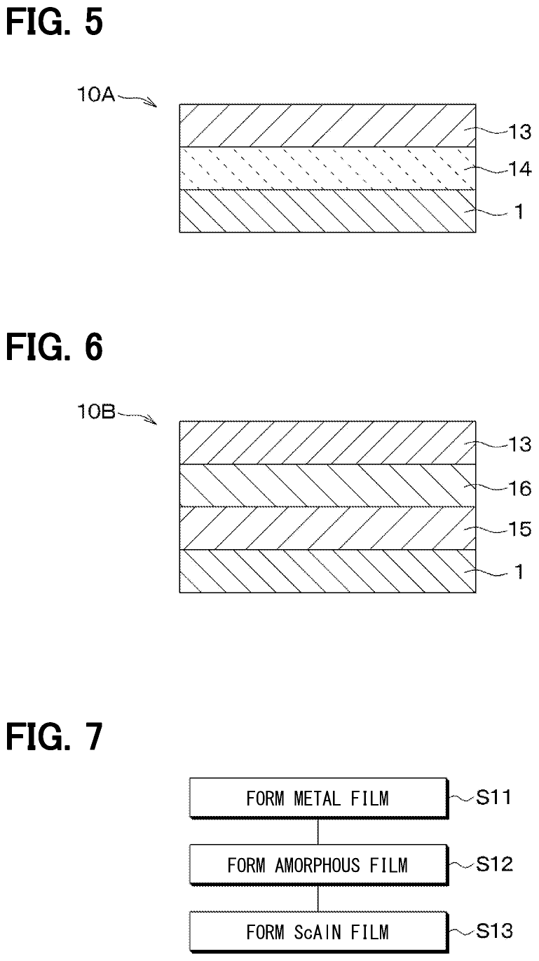

As shown in FIG. 5, a piezoelectric film laminated body 10A according to a third embodiment includes a substrate 1, an amorphous film 14 having conductivity, and a ScAlN film 13.

The amorphous film 14 is disposed on the substrate 1. The amorphous film 14 is in contact with a surface of the substrate 1. The ScAlN film 13 is disposed on the amorphous film 14. The ScAlN film 13 is in contact with a surface of the amorphous film 14. The configurations of the substrate 1 and the ScAlN film 13 are the same as those in the first embodiment.

The amorphous film 14 is a film made of an amorphous material having conductivity. In the present specification, “conductivity” means that the electrical resistivity (that is, the volume resistivity) is 10⁻² Ω·m or less.

Examples of the material constituting the amorphous film 14 include conductive metal oxides and conductive metal nitrides. Examples of the conductive metal oxide include Ru oxide and indium tin oxide (ITO).

A manufacturing method of the piezoelectric film laminated body 10A according to the present embodiment includes forming the amorphous film 14 and forming the ScAlN film 13.

When forming the amorphous film 14, a metal film (not shown) made of a material containing a metal element capable of forming a conductive metal oxide or a conductive metal nitride is formed. Then, the entire metal film is oxidized or nitrided to form the amorphous film 14. In this case, the entire metal film becomes the amorphous film 14. The amorphous film 14 may be formed on the metal film by oxidizing or nitriding a surface layer of the metal film.

The present disclosure is not limited to the above examples, and when forming the amorphous film 14, the amorphous film 14 may be formed by a film forming method. Examples of the film forming method include a physical vapor deposition method and a chemical vapor deposition method. When forming the amorphous film 14 by the film forming method, “lowering a substrate temperature”, “increasing a film forming pressure”, “increasing an input power to increase a film formation speed”, and the like are performed with respect to conditions for forming a film having a crystal structure. Accordingly, the amorphous film 14 can be formed.

When the amorphous film 14 is formed by the film forming method, the amorphous film 14 may be formed in contact with a surface of a metal film. For example, the amorphous film 14 may be formed in contact with a surface of a metal film made of a material containing Mo. In this case, as described in the first embodiment, the metal film 11 can be disposed in contact with the surface of the substrate 1 as a base member made of a material other than AlN.

The ScAlN film 13 can be formed in a manner similar to that of the first embodiment. Also in the present embodiment, the effects of the configurations common to those of the first embodiment can be obtained in the same manner as in the first embodiment.

### Fourth Embodiment

As shown in FIG. 6, a piezoelectric film laminated body 10B according to a fourth embodiment includes a substrate 1, a metal film 15, an amorphous film 16 having conductivity, and a ScAlN film 13. In the present embodiment, the metal film 15 and the amorphous film 16 are used as a lower electrode in a device.

The structure of the substrate 1 is the same as that of the first embodiment. The metal film 15 is a film made of a metal material. The metal film 15 is disposed on the substrate 1. The metal film 15 is in contact with a surface of the substrate 1.

The amorphous film 16 is disposed on the metal film 15. The amorphous film 16 is in contact with a surface of the metal film 15. The amorphous film 16 is formed by performing an ion implantation or a plasma treatment to a surface layer of the metal film 15 as described below.

As shown in FIG. 7, a manufacturing method of the piezoelectric film laminated body 10B of the present embodiment includes S11 of forming the metal film 15, S12 of forming the amorphous film 16, and S13 of forming the ScAlN film 13. In S11, the metal film 15 as a base member for forming the amorphous film 16 is formed on the substrate 1. In S12, the amorphous film 16 is formed by performing an ion implanting or a plasma treatment to the metal film 15.

In the ion implantation to the metal film 15, metal ions, rare gas ions or the like are used as ion implantation species. By applying energy of about several tens to 100 keV to the surface layer of the metal film 15, the amorphous film 16 having a thickness of about several tens to 100 nm can be formed. By using metal ions, rare gas ions, or the like as the ion-implanted species, the conductivity of the ion-implanted metal can be maintained.

The plasma treatment to the metal film 15 can be performed by a method described in Schneider, M.; Bittner, A.; Patocka, F.; et al. “Impact of the surface-near silicon substrate properties on the microstructure of sputter-deposited AlN thin films” APPLIED PHYSICS LETTERS, Volume: 101: 22, Articles Number: 221602, Issue Date: Nov. 26, 2012, which is incorporated herein by reference. That is, a chamber configuration generally used for dry etching (that is, a layout in which a substrate and a counter electrode are arranged in parallel) is used. In this chamber configuration, plasma is generated by high-frequency discharge in the same manner as in a normal dry etching process. At this time, by introducing only Ar gas as material gas, etching of the metal film 15 can be minimized, and the surface layer of the metal film 15 can be amorphized.

The ScAlN film 13 can be manufactured in a manner similar to that of the first embodiment. Also in the present embodiment, the effects of the configurations common to those of the first embodiment can be obtained in the same manner as in the first embodiment. Also in the present embodiment, when the metal film 15 is made of a material containing Mo, the metal film 15 can be disposed in contact with the surface of the substrate 1 as a base member made of a material other than AlN. In this case, the amorphous film 16 is made of a material containing Mo.

### Fifth Embodiment

A microphone 20 of a fifth embodiment shown in FIG. 5 uses the piezoelectric film laminated body 10 of the first embodiment. The microphone 20 includes a pressure receiving portion 21 and a supporter 22. The pressure receiving portion 21 is a film-like portion that receives sound pressure. The supporter 22 supports the pressure receiving portion 21.

The supporter 22 defines a space 23 into which the pressure receiving portion 21 is deformed by receiving sound pressure. The supporter 22 supports the pressure receiving portion 21 above the space 23 so that the pressure receiving portion 21 can be deformed when the pressure receiving portion 21 receives sound pressure. The supporter 22 is made of Si.

The pressure receiving portion 21 includes a piezoelectric film 24, a lower electrode 25, an upper electrode 26, and an insulating film 27. As the piezoelectric film 24, the ScAlN film 13 of the first embodiment is used. As the lower electrode 25, the metal film 11 and the amorphous film 12 of the first embodiment are used. The upper electrode 26 is in contact with the upper surface of the piezoelectric film 24. The lower electrode 25 and the upper electrode 26 are electrodes for recovering electric charge generated in the piezoelectric film 24 when the pressure receiving portion 21 is deformed. The insulating film 27 covers the space 23 and the peripheral of the space 23 of the supporter 22. The insulating film 27 is a silicon oxide film.

The lower electrode 25 is provided on a part of the insulating film 27 located above the space 23. The piezoelectric film 24 is formed on the upper surface of the lower electrode 25 and the surface of a part of the insulating film 27 on which the lower electrode 25 is not formed.

In the microphone 20 configured in this way, the pressure receiving portion 21 receives sound pressure and is deformed. When the pressure receiving portion 21 is deformed into a downward-convex shape, compressive stress is generated in the in-plane direction of the piezoelectric film 24. At this time, an electric charge is generated on the surface of the piezoelectric film 24 due to piezoelectric effect. Further, when the pressure receiving portion 21 is deformed into an upward-convex shape, tensile stress is generated in the in-plane direction of the piezoelectric film 24. At this time, due to piezoelectric effect, an electric charge having the opposite polarity to that when the compressive stress is generated is generated on the surface of the piezoelectric film 24. By recovering the generated electric charge through the lower electrode 25 and the upper electrode 26, the sound pressure applied to the pressure receiving portion 21 can be detected.

According to the present embodiment, the ScAlN film 13 of the first embodiment is used as the piezoelectric film 24. As described in the first embodiment, the ScAlN film 13 has high piezoelectricity because ScAlN has high crystallinity. Therefore, the sensitivity of the microphone 20 can be increased.

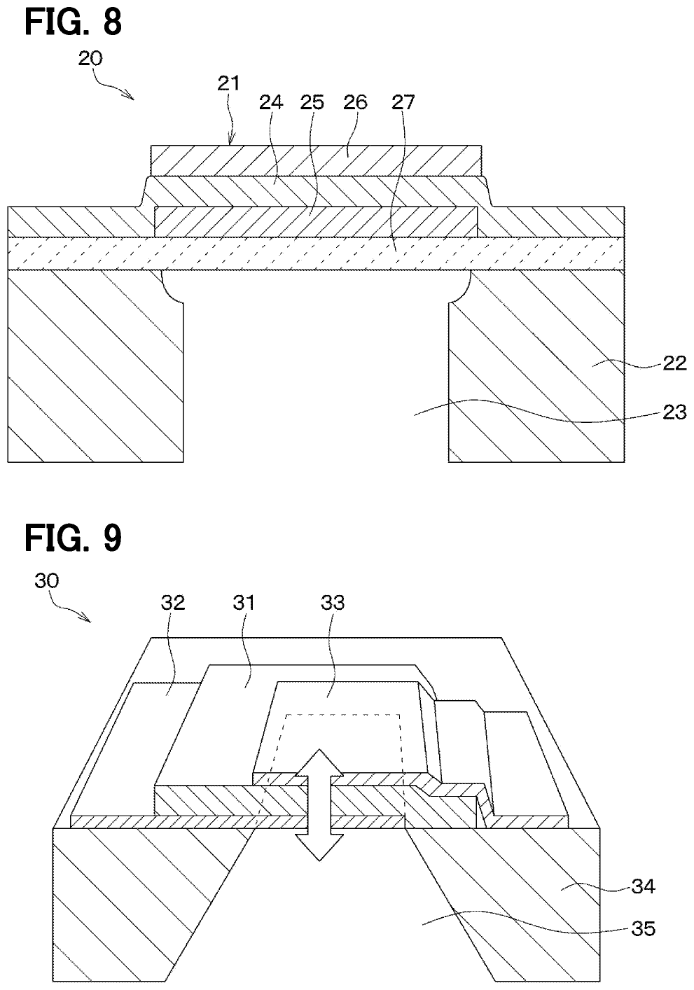

In the present embodiment, the pressure receiving portion 21 includes the insulating film 27. However, the insulating film 27 may be a conductive film different from the lower electrode 25. Furthermore, in the present embodiment, the insulating film 27 is formed so that a neutral axis in the deflection deformation of the pressure receiving portion 21 does not present in the piezoelectric film 24. When the neutral axis in the deflection deformation of the pressure receiving portion 21 is not present in the piezoelectric film 24 by making the lower electrode 25 thicker than the upper electrode 26 or the like, the pressure receiving portion 21 may not include the insulating film 27. Furthermore, in the present embodiment, the piezoelectric film 24, the lower electrode 25, and the upper electrode 26 have the shapes shown in FIG. 8. However, shapes thereof are not limited to the shapes as shown in FIG. 8.

In the microphone 20 of the present embodiment, the piezoelectric film laminated body 10 of the first embodiment is used. However, the piezoelectric film laminated body 10A of the third embodiment may also be used. In this case, the amorphous film 14 having conductivity is used alone for the lower electrode 25. Alternatively, the amorphous film 14 having conductivity and a metal film in contact with a lower surface of the amorphous film 14 may be used for the lower electrode 25. Similarly, the piezoelectric film laminated body 10B of the fourth embodiment may also be used for the microphone 20 of the present embodiment. In this case, the metal film 15 and the amorphous film 16 having conductivity are used for the lower electrode 25.

### Sixth Embodiment

A bulk acoustic wave (BAW) resonator 30 of a sixth embodiment shown in FIG. 9 is a BAW device using the piezoelectric film laminated body 10 of the first embodiment. The BAW resonator 30 includes a piezoelectric film 31, a lower electrode 32, an upper electrode 33, and a supporter 34.

As the piezoelectric film 31, the ScAlN film 13 of the first embodiment is used. As the lower electrode 32, the metal film 11 and the amorphous film 12 of the first embodiment are used. The upper electrode 33 is in contact with the upper surface of the piezoelectric film 31. The lower electrode 32 and the upper electrode 33 are electrodes that apply an alternating current (AC) electric field to the piezoelectric film 31 to vibrate the piezoelectric film 31 in the film thickness direction.

The supporter 34 supports the piezoelectric film 31, the lower electrode 32, and the upper electrode 33. The supporter 34 defines a space 35 for the piezoelectric film 31 to vibrate when AC electric field is applied to the piezoelectric film 31. The supporter 34 is made of Si. The lower electrode 32 faces the space 35 of the supporter 34. In the present embodiment, the piezoelectric film 31 is formed on the surface of the lower electrode 32 and on the surface of the supporter 34.

In the BAW resonator 30 configured in this way, when voltage is applied between the upper electrode 33 and the lower electrode 32, the piezoelectric film 31 vibrates in the film thickness direction indicated by the arrow in FIG. 9 due to inverse piezoelectric effect. When a sinusoidal voltage waveform is applied, this vibration also becomes a sinusoidal vibration waveform. When the frequency coincides with the resonance frequency of the mechanical vibration, the impedance between the upper electrode 33 and the lower electrode 32 changes significantly. As a result, the BAW resonator 30 of the present embodiment becomes an electrical resonator. By using multiple resonators configured as described above and connecting the resonators in a circuit, a filter operation can be realized.

According to the present embodiment, the ScAlN film 13 of the first embodiment is used as the piezoelectric film 31. As described in the first embodiment, the ScAlN film 13 has high piezoelectricity because ScAlN has high crystallinity. Therefore, a band of a filter can be widened.

In the BAW resonator 30 of the present embodiment, the supporter 34 defines the space 35. However, the supporter 34 may not define the space 35. In this case, the BAW resonator 30 may include an acoustic multilayer film between the lower electrode 32 and the supporter 34.

In the BAW resonator 30 of the present embodiment, the piezoelectric film laminated body 10 of the first embodiment is used. However, the piezoelectric film laminated body 10A of the third embodiment may also be used. In this case, the amorphous film 14 having conductivity is used alone for the lower electrode 32. Alternatively, the amorphous film 14 having conductivity and a metal film in contact with a lower surface of the amorphous film 14 may be used for the lower electrode 32. Similarly, the piezoelectric film laminated body 10B of the fourth embodiment may also be used for the BAW resonator 30 of the present embodiment. In this case, the metal film 15 and the amorphous film 16 having conductivity are used for the lower electrode 32.

### Seventh Embodiment

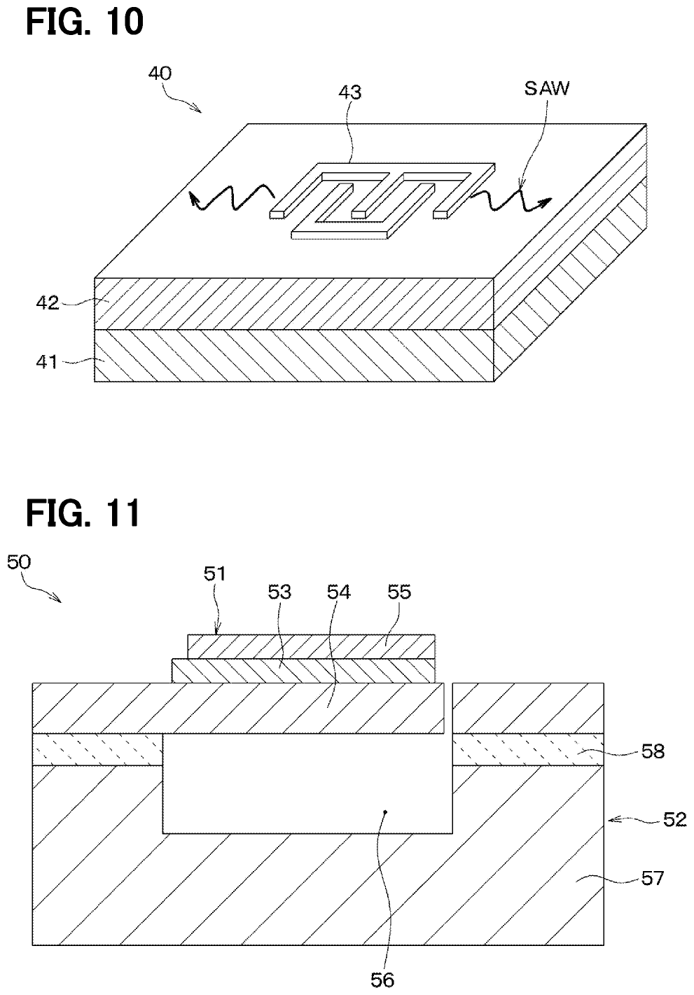

A surface acoustic wave (SAW) device 40 of a seventh embodiment shown in FIG. 10 uses the piezoelectric film laminated body 10 of the first embodiment.

The SAW device 40 includes a substrate 41, a piezoelectric film 42, and a comb tooth electrode 43. The substrate 41 is made of Si. As the piezoelectric film 42, the piezoelectric film laminated body 10 of the first embodiment is used. The piezoelectric film 42 is disposed on a surface of the substrate 41. The comb tooth electrode 43 is disposed on a surface of the piezoelectric film 42. The comb tooth electrode 43 excites SAW on the piezoelectric film 42, or receives SAW propagating through the piezoelectric film 42. The comb tooth electrode 43 is composed of Mo. Examples of the SAW device 40 include a SAW resonator, a SAW filter, and the like.

Although not shown, there is a 1-port type SAW resonator as an example of the SAW resonator. In this SAW resonator, reflectors are arranged on both sides of the comb tooth electrode 43 on the surface of the piezoelectric film 42. In this SAW resonator, SAW excited at the comb tooth electrode 43 is reflected at the both reflectors, so that a standing wave is generated. As a result, a resonator is realized.

Further, although not shown, another example of the SAW device is a transversal SAW filter. In this SAW filter, the comb tooth electrode 43 includes an input electrode and an output electrode. The SAW excited by the input electrode propagates along the surface of the piezoelectric film 42 and is detected by the output electrode. This makes it possible to extract an electric signal in a specific frequency band. According to the present embodiment, the piezoelectric film laminated body 10 of the first embodiment is used as the piezoelectric film 42. The ScAlN film 13 included in the piezoelectric film laminated body 10 has high piezoelectricity because ScAlN has high crystallinity. Therefore, a band of a filter can be widened.

Each of the substrate 41 and the comb tooth electrode 43 may be made of a material different from the above-described materials. As the piezoelectric film 42, the piezoelectric film laminated body 10A of the third embodiment or the piezoelectric film laminated body 10B of the fourth embodiment may also be used.

### Eighth Embodiment

A micro electro mechanical systems (MEMS) resonator 50 of an eighth embodiment shown in FIG. 11 uses the piezoelectric film laminated body 10 of the first embodiment.

The MEMS resonator 50 includes a three-layer structure 51 and a supporter 52. The three-layer structure 51 includes a piezoelectric film 53, a lower electrode 54, and an upper electrode 55.

As the piezoelectric film 53, the ScAlN film 13 of the first embodiment is used. As the lower electrode 54, the metal film 11 and the amorphous film 12 of the first embodiment are used. The upper electrode 55 is in contact with an upper surface of the piezoelectric film 53. The lower electrode 54 and the upper electrode 55 are electrodes that apply AC electric field to the piezoelectric film 53 to expand and contract the piezoelectric film 53 in the in-plane direction of the piezoelectric film 53.

The supporter 52 defines a space 56. The supporter 52 supports the three-layer structure 51 in a state in which the three-layer structure 51 can vibrate on the upper side of the space 56. In the present embodiment, one end of the three-layer structure 51 in one direction is fixed to the supporter 52, and the other end of the three-layer structure 51 in the one direction is free. That is, the three-layer structure 51 has a so-called a cantilever beam structure. The supporter 52 includes a substrate 57 and an insulating film 58. The substrate 57 is made of Si. The insulating film 58 is formed on a surface of the substrate 57. The insulating film 58 is a silicon oxide film. The lower electrode 54 is formed on a surface of the insulating film 58.

The thickness of the lower electrode 54 is equal to or greater than the total thickness of the upper electrode 55 and the piezoelectric film 53. Therefore, the neutral axis in the deflection deformation of the three-layer structure 51 is in the lower electrode 54. When voltage is applied between the upper electrode 55 and the lower electrode 54, the piezoelectric film 53 expands and contracts in the in-plane direction of the film due to inverse piezoelectric effect. Then, the entire of the three-layer structure 51 is deformed. When a sinusoidal voltage waveform is applied, this deflection deformation also becomes a sinusoidal vibration. When the frequency matches with the resonance frequency of the deflection vibration, the impedance between the upper electrode 55 and the lower electrode 54 changes significantly. Thereby, this becomes an electrical resonator. This resonator can be used to generate a reference frequency required for an operation of an arithmetic circuit or the like.

According to the present embodiment, the ScAlN film 13 of the first embodiment is used as the piezoelectric film 53. As described in the first embodiment, the ScAlN film 13 has high piezoelectricity because ScAlN has high crystallinity. Therefore, the characteristics can be improved.

If the substrate 57 is an insulator, the insulating film 58 may not be formed. In the MEMS resonator 50 of the present embodiment, the piezoelectric film laminated body 10 of the first embodiment is used. However, the piezoelectric film laminated body 10A of the third embodiment may also be used. In this case, the amorphous film 14 having conductivity is used alone for the lower electrode 54. Alternatively, the amorphous film 14 having conductivity and a metal film in contact with a lower surface of the amorphous film 14 may be used for the lower electrode 54. Similarly, the piezoelectric film laminated body 10B of the fourth embodiment may also be used for the MEMS resonator 50 of the present embodiment. In this case, the metal film 15 and the amorphous film 16 having conductivity are used for the lower electrode 54.

### Other Embodiments

The piezoelectric film laminated body 10, 10A, and 10B according to the first to fourth embodiments include the ScAlN film 13. However, even when the piezoelectric film laminated body 10, 10A and 10B include a film made of an Ulzite-based material such as AlN or zinc oxide (ZnO) instead of the ScAlN film 13, there is a possibility that the same effects as those of the first embodiment can be obtained.

The present disclosure is not limited to the foregoing description of the embodiments and can be modified within the scope of the present disclosure. The present disclosure may also be varied in many ways. Such variations are not to be regarded as departure from the disclosure, and all such modifications are intended to be included within the scope of the disclosure. The above-described embodiments are not independent of each other, and can be appropriately combined except when the combination is obviously impossible. In each of the above-described embodiments, individual elements or features of a particular embodiment are not necessarily essential unless it is specifically stated that the elements or the features are essential, or unless the elements or the features are obviously essential in principle. Further, in each of the above-described embodiments, when numerical values such as the number, quantity, range, and the like of the constituent elements of the embodiment are referred to, except in the case where the numerical values are expressly indispensable in particular, the case where the numerical values are obviously limited to a specific number in principle, and the like, the present disclosure is not limited to the specific number. Furthermore, a material, a shape, a positional relationship, or the like, if specified in the above-described example embodiments, is not necessarily limited to the specific material, shape, positional relationship, or the like unless it is specifically stated that the material, shape, positional relationship, or the like is necessarily the specific material, shape, positional relationship, or the like, or unless the material, shape, positional relationship, or the like is obviously necessary to be the specific material, shape, positional relationship, or the like in principle.

What is claimed is:

1. A piezoelectric film laminated body comprising:
a metal film;
an amorphous film having an insulation property and disposed on the metal film; and
a scandium aluminum nitride film disposed on the amorphous film and being in contact with a surface of the amorphous film.

2. The piezoelectric film laminated body according to claim 1, wherein
the amorphous film has a film thickness of 1.0 nm or more.

3. The piezoelectric film laminated body according to claim 1, wherein
the amorphous film is made of a material containing molybdenum oxide.

4. The piezoelectric film laminated body according to claim 3, wherein
the metal film is made of a material containing molybdenum.

5. The piezoelectric film laminated body according to claim 4, further comprising
a base member made of a material other than aluminum nitride, wherein
the metal film is disposed in contact with a surface of the base member.

6. A piezoelectric film laminated body comprising:
an amorphous film having conductivity; and
a scandium aluminum nitride film disposed on the amorphous film and being in contact with a surface of the amorphous film.

7. The piezoelectric film laminated body according to claim 6, further comprising:
a base member made of a material other than aluminum nitride; and
a metal film made of a material containing molybdenum and disposed on a surface of the base member, wherein
the amorphous film is disposed on the metal film.

8. A manufacturing method of a piezoelectric film laminated body, comprising:
forming a metal film;
forming an amorphous film having an insulation property on the metal film; and
forming a scandium aluminum nitride film on the amorphous film to be in contact with a surface of the amorphous film, wherein
the forming the amorphous film includes oxidizing or nitriding a surface layer of the metal film to form the amorphous film.

9. The manufacturing method according to claim 8, wherein
the forming the metal film includes forming the metal film made of a material containing at least one metal element selected from a group consisting of molybdenum, aluminum, and titan.

10. The manufacturing method according to claim 8, wherein
the forming the metal film includes forming the metal film made of a material containing molybdenum, and
the forming the amorphous film includes oxidizing a surface layer of the metal film to form the amorphous film made of a material containing molybdenum oxide.

11. The manufacturing method according to claim 8, further comprising
patterning the metal film after the forming the metal film, wherein
the forming the amorphous film is performed after the forming the metal film and before the patterning the metal film.

12. The manufacturing method according to claim 8, further comprising
removing a surface layer of the amorphous film to remove contaminants on the amorphous film after the forming the amorphous film and before the forming the scandium aluminum nitride film, wherein
the forming the amorphous film includes forming the amorphous film to have a thickness that is obtained by adding a target thickness of the amorphous film after the contaminants are removed and a thickness of the amorphous film to be removed by the removing the surface layer of the amorphous film.

13. A manufacturing method of a piezoelectric film laminated body, comprising:
forming an amorphous film having conductivity; and
forming a scandium aluminum nitride film on the amorphous film to be in contact with a surface of the amorphous film, wherein
the forming the amorphous film includes performing an ion implantation or a plasma treatment to a metal film to form the amorphous film.
